(19) United States
(12) Patent Application Publication
(10) Pub. No.: US 2007/0164435 A1
(43) Pub. Date: Jul. 19, 2007

(54) SEMICONDUCTOR DEVICE

(75) Inventors: Kazutaka Koshiishi, Tokyo (JP); Mitsuaki Katagiri, Tokyo (JP); Satoshi Isa, Tokyo (JP); Fumiyuki Osanai, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 11/613,914

(22) Filed: Dec. 20, 2006

(30) Foreign Application Priority Data
Jan. 13, 2006 (JP) 2006-005607

(51) Int. Cl. H01L 23/52

(52) U.S. Cl. 257/758; 257/E23.142

(57) ABSTRACT

To reduce noise between a power supply wiring and ground wiring especially in a small, high-density semiconductor device for high-speed operation. A semiconductor device having a second dielectric layer 5 made of dielectric material of which the dielectric loss tan 6 is at least 0.2 and interposed between a power supply wiring layer 6 electrically connected to a semiconductor chip and a ground wiring layer 4, so composed that a dielectric loss generated in the second dielectric layer 5 acts as a low pass filter of the power supply wiring layer 6, and having a first dielectric layer 3 made of dielectric material whose dielectric loss is less than the dielectric loss tan 6 of the second dielectric layer 5 and interposed between a signal wiring layer 2 electrically connected to the semiconductor chip and the ground wiring layer 4.

### FIELD OF THE INVENTION

This invention relates to a semiconductor device suppressing noise between power supply wiring and ground wiring or signal wires.

### BACKGROUND OF THE INVENTION

A semiconductor device has been developed to increase an operation speed and to decrease power consumption these days. Consequently an influence of noise occurred between a power supply wiring and a ground wiring of a circuit board to signal transmission has been so increased that various kinds of problems which needed not to care hitherto are now generating. Some of those problems are signal integrity (SI) and power integrity (PI). The SI means to keep quality of transmission waveform during signal transmission in a semiconductor device, and it is a big problem to transmit digital signals of wide frequency components without deterioration. The PI means to keep quality of power supply, and instability of power supply causes lack of electrical power supply to signal lines connected to it, distortion of signal waveforms and radiated noise emissions.

There are many factors of signal deterioration and one of those factors is attenuation of signal waveform induced by a dielectric loss of a dielectric between signal wiring and ground wiring. The deteriorated signal waveform and its causes are described with reference to FIGS. 6A and 6B. Referring to FIG. 6A, a signal waveform 101 is an ideal signal waveform and each of a rising flank, plateau and falling flank of the voltage depicts a rectangular wave form in straight lines. Referring to FIG. 6B, a signal waveform 102 illustrates a signal wave influenced by a dielectric loss and flank edges of the rectangular wave are rounded. When the roundness of the edges becomes bigger, the eye aperture of eye pattern becomes narrower to cause obstruction to the signal transmission. To suppress this problem, so far, low relative permittivity (ε r) materials or low dielectric loss (tan δ; a ratio of conductance and capacitance) materials were used for dielectrics between signal wirings and ground wirings.

One of noises occurring between a power supply wiring and ground wiring is a simultaneous switching noise. This noise will be explained with reference to FIG. 7. In the electrical circuit of FIG. 7, electric currents flow in all of wires 107a to 107n simultaneously when all of transistors 108 are switched on simultaneously and a current I in VDD wire 105 should be sufficient to let the currents to flow in all the wires 107a to 107n. Then a large electric current flows in the VDD wire 105 and a noise occurs by a large electromotive force by the large current. This is the simultaneous switching noise. To cope with this problem, countermeasures have been employed, e.g., by using multi-layer board to expand areas of power supply wiring and ground wiring, or implementing a bypass condenser on a board.

For example, a high permittivity portion is disposed between signal and ground wirings, and a, low permittivity portion is interposed between signal wirings so as to make a capacitance between signal wirings lower than that between signal and ground wirings to suppress noise in Patent Document 1. In Patent Document 2, a shield metal layer 31 fixed at a ground level or a power supply voltage level is interposed between a semiconductor substrate and a signal wiring layer. Patent Document 3 discloses a board provided with a signal line at least on a surface out of a surface and its rear surface of the board, a ground layer opposing to a signal line via a first insulating layer within the board, and a power supply line sandwiched between two ground layers via second insulating layers, wherein the first insulating layer 4 is set at a permittivity ε of 5 or lower, and the second insulating layer is set at a permeability μ, of 2 or higher and a permittivity ε of 10 or higher. In Patent Document 4, power supply lines are surrounded with a magnetic material and a power supply wiring layer is sandwiched between two ground layers to suppress noise.

[Patent Document 1] JP Patent Kokai Publication No. JP-A-09-321176

[Patent Document 2] JP Patent Kokai Publication No. JP-P2000-286385A

[Patent Document 3] JP Patent Kokai Publication No. JP-P2001-77539A

[Patent Document 4] JP Patent Kokai Publication No. JP-P2000-183540A

### SUMMARY OF THE DISCLOSURE

However, when a dielectric loss of the dielectric interposed between signal and ground wirings is small, the behavior of signal waveform becomes immoderate and it becomes liable to generate a ringing (multiple reflections induced by discordance of impedance occurred at a connection of each transmission line or components) or noise by an overshoot and/or undershoot in the signal wiring. Referring to FIG. 6C, both overshoot portion 103 and undershoot portion 104 of the signal waveform are generated because a signal from a driver exceeds high and low plateau levels transiently at rising and falling times respectively. This will lead to a deterioration in the signal waveform, and the signal cannot be transmitted properly for this reason.

Besides that, there is a requirement for a small, high-density semiconductor device to increase an operation speed has been limiting expansion of power supply and ground wiring areas or keeping a space to implement a bypass condenser on a board. Therefore a means to reduce noise between power supply and ground wirings is necessary except the means mentioned above, that is, without increasing areas of power supply and ground wiring or a space to implement a bypass condenser.

It is a main object of the present invention to reduce noise between power supply wiring and ground wiring or in signal wires especially in a small, high-density semiconductor device for high-speed operation.

According to a first aspect of the present invention, there is provided a semiconductor device in which a dielectric material whose dielectric loss tan δ is at least 0.2 is used for a dielectric layer interposed between a power supply wiring layer electrically connected to a semiconductor chip and a ground wiring layer (mode 1).

Preferably, the semiconductor device of the present invention is so composed that a transmission loss generated in the dielectric layer acts as a low pass filter of the power supply wiring layer (mode 2).

Preferably, the semiconductor device of the present invention further comprises another dielectric layer interposed between a signal wiring layer electrically connected to the semiconductor chip and the ground wiring layer, in which a dielectric material having a dielectric loss less than the dielectric loss tan 6 of the dielectric layer is used for the another dielectric layer (mode 3).

According to a second aspect of the present invention, there is provided a semiconductor device in which a dielectric material whose dielectric loss tan δ is at least 0.2 is used for a dielectric layer interposed between a signal wiring layer electrically connected to a semiconductor chip and a ground wiring layer (mode 4).

Preferably, the semiconductor device of the present invention is so composed that a transmission loss generated in the dielectric layer reduces noise occurring in the signal wiring layer (mode 5).

The meritorious effects of the present invention are summarized as follows.

According to the present invention (modes 1 to 3), it is possible to reduce noise between power supply and ground wirings due to a transmission loss occurred in a dielectric layer.

According to the present invention (modes 4 and 5), it is possible to reduce noise in a signal wiring layer due to a transmission loss occurred in a dielectric layer.

### BRIEF DESCRIPTIONS OF THE DRAWINGS

FIG. 1 is a partial cross-sectional view for illustrating a semiconductor device in accordance with example 1 of the present invention.

FIG. 2 is a cross-sectional view of a simulation model of a ground wiring layer, a second dielectric layer and a power supply wiring layer of the semiconductor device in accordance with example 1 of the present invention.

FIG. 3 is a graph obtained by an electromagnetic field simulation by the model of FIG. 2 to explain a transmission loss between a power supply wiring layer and a ground wiring layer.

FIG. 4 is a graph to explain noise between power supply and ground wirings when a driver of the semiconductor device in accordance with example 1 of the present invention is operated at an operation frequency of 1 GHz.

FIG. 5 is a partial cross-sectional view for illustrating a semiconductor device in accordance with example 2 of the present invention.

FIGS. 6A, 6B and 6C illustrate signal waveforms flowing in signal wiring, showing an ideal pattern, a pattern influenced by dielectric loss and a pattern of less dielectric loss, respectively.

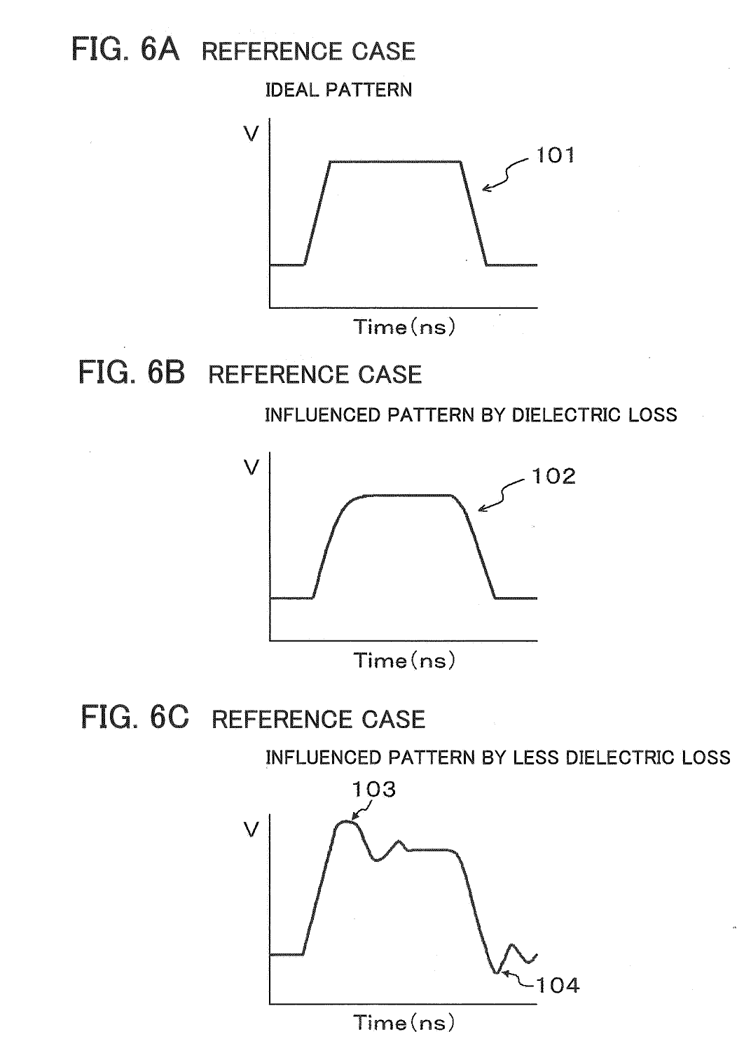

FIG. 7 is an electric circuit to explain a simultaneous switching noise.

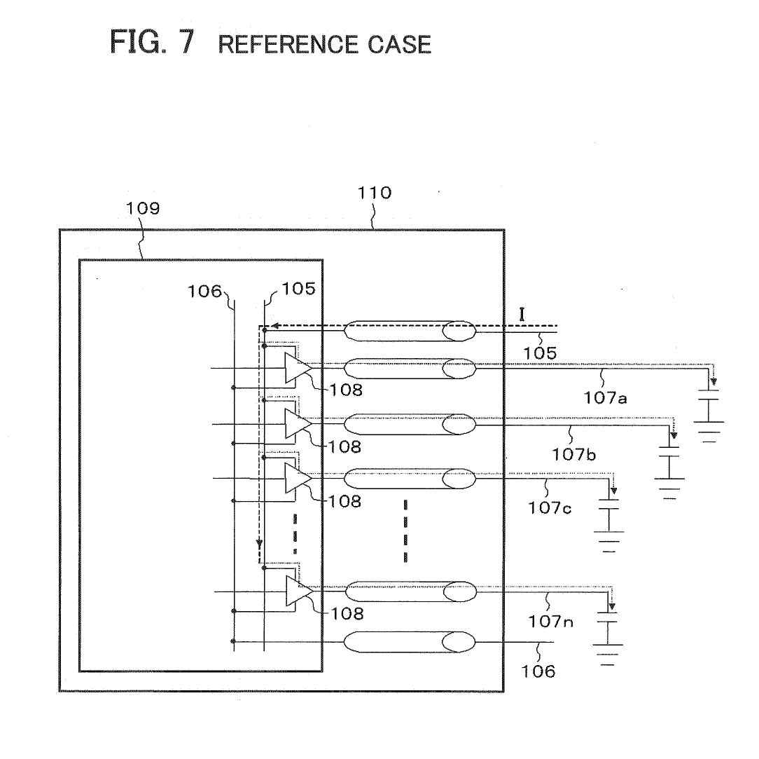

### PREFERRED MODES OF THE INVENTION

### EXAMPLE 1

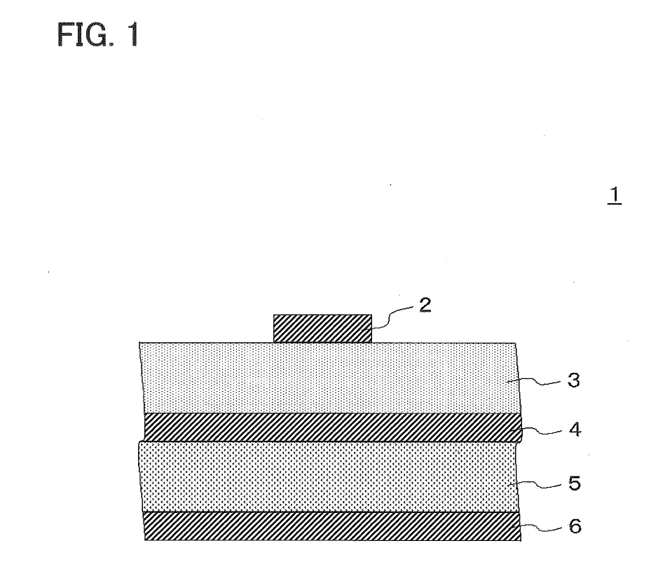

A semiconductor device in accordance with example 1 of the present invention is explained with respect to drawings. FIG. 1 is a partial cross-sectional view for illustrating a semiconductor device in accordance with example 1 of the present invention.

A semiconductor device 1 is used for a semiconductor package (micro-computer or memory, for example) in which circuit-patterned semiconductor chips (not shown) are mounted on the package board, or a mounting board (memory module or mother board, for example) mounting a semiconductor package onto a circuit board. The semiconductor device 1 contains a signal wiring layer 2, a first dielectric layer 3, a ground wiring layer 4, a second dielectric layer 5 and a power supply wiring layer 6 in a multi-layer (laminated) wiring portion of a package board or a circuit board, for example.

The signal wiring layer 2 is a wiring layer for signal transmission made of a conductor and disposed on the first dielectric layer 3 with a determined pattern (not shown). The signal wiring layer 2 is electrically connected to signal terminals of the semiconductor chips (not shown). A metal, e.g., cupper, can be used for the signal wiring layer 2. The thickness of the signal wiring layer 2 can be 0.01 to 0.03 mm, for example.

The first dielectric layer 3 is a layer made of dielectric (insulator) and interposed between the signal wiring layer 2 and the ground wiring layer 4. A dielectric material FR4 (Flame Retardant Type; flame retardant material made of a composite material of glass fiber and epoxy-resin) having a dielectric loss of tan δ=0.02 to 0.03 or dielectric material whose dielectric loss is greater than FR4 (tan δ is greater than or equal to 0.03, e.g.) can be used for the first dielectric layer 3. The thickness of the first dielectric layer 3 can be 0.02 to 0.08 mm, for example.

The ground wiring layer 4 is a wiring layer for ground made of conductor and interposed between the first dielectric layer 3 and the second dielectric layer 5. The ground wiring layer 4 is electrically connected to ground terminals of the semiconductor chips (not shown). A metal, e.g., cupper, can be used for the ground wiring layer 4. The thickness of the ground wiring layer 4 can be 0.01 to 0.03 mm, for example.

The second dielectric layer 5 is a layer made of a dielectric being different from the dielectric for the first dielectric layer 3 and interposed between the ground wiring layer 4 and a power supply wiring layer 6. Dielectric material of which the dielectric loss is greater than FR4 (tan δ is greater than or equal to 0.2) is used as the second dielectric layer 5. For example, a composite material of organic resins such as phenol resin (tan δ=0.05 to 0.1), poly vinylchloride resin, etc., mixed with conductive particles such as metal particles, carbon, etc., the dielectric loss (tan δ) of which is adjusted to greater than or equal to 0.2 by changing the composition of the organic resin and conductive particles, can be used. The thickness of the second dielectric layer 5 can be 0.02 to 0.08 mm, for example. Other materials than mentioned above will be possible for the second dielectric 5 as far as it has a dielectric loss tan δ greater than or equal to 0.2. And also the material characteristics to select the dielectric 5 is only a dielectric loss tan δ and both permittivity and permeability are not considered.

The power supply wiring layer 6 is a wiring layer for power supply made of a conductor and disposed on one side of the second dielectric layer 5 opposing to the side of the ground wiring layer 4. The power supply wiring layer 6 is electrically connected to power supply terminals of the semiconductor chip (not shown). A metal, e.g., cupper, can be used for the power supply wiring layer 6. The thickness of the power supply wiring layer 6 can be 0.01 to 0.03 mm, for example.

An operation of the semiconductor device according to example 1 will be explained. When the power supply wiring layer 6 and ground wiring layer 4 are on (conducting), a transmission loss generated in the second dielectric layer 5 acts as a low pass filter of the power supply wiring layer 6 and reduces the noise occurring between power supply wiring layer 6 and the ground wiring layer 4.

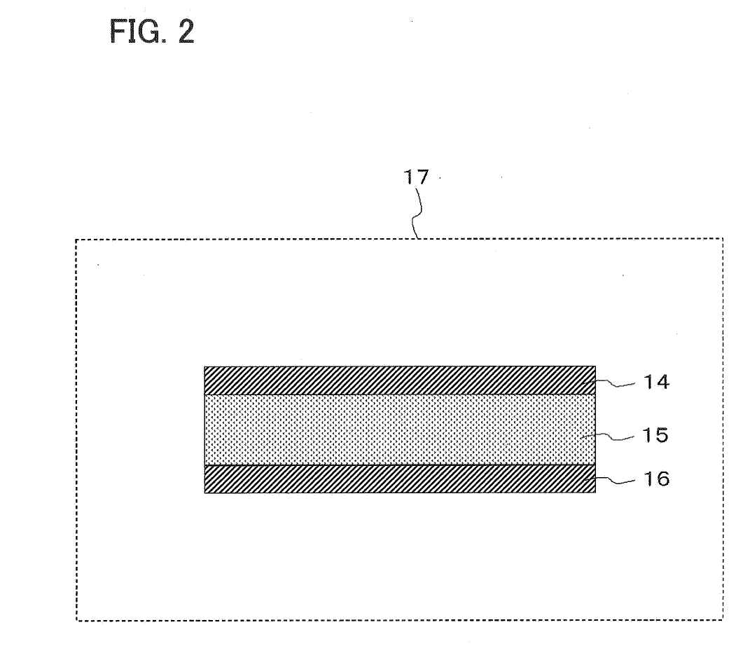

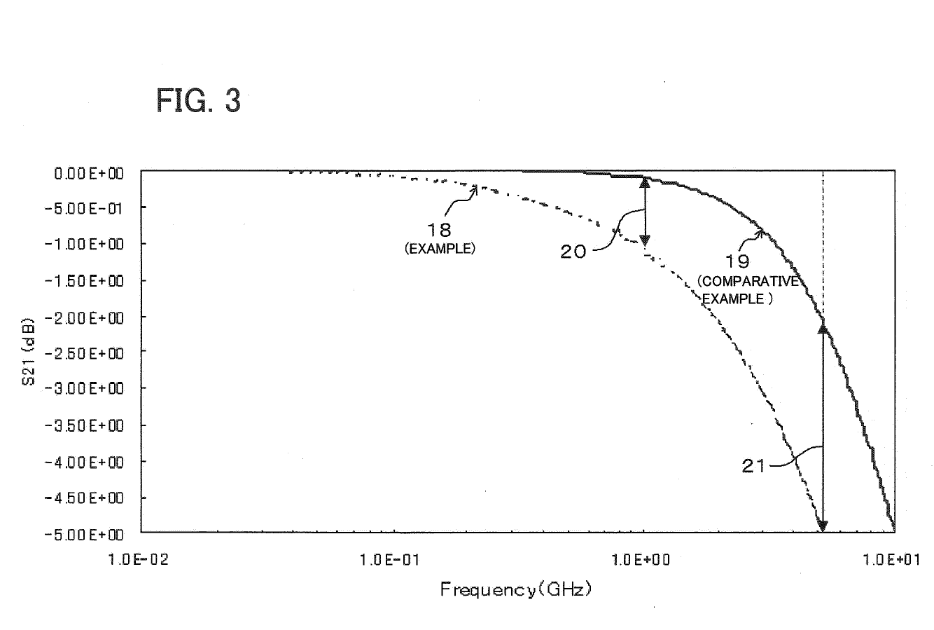

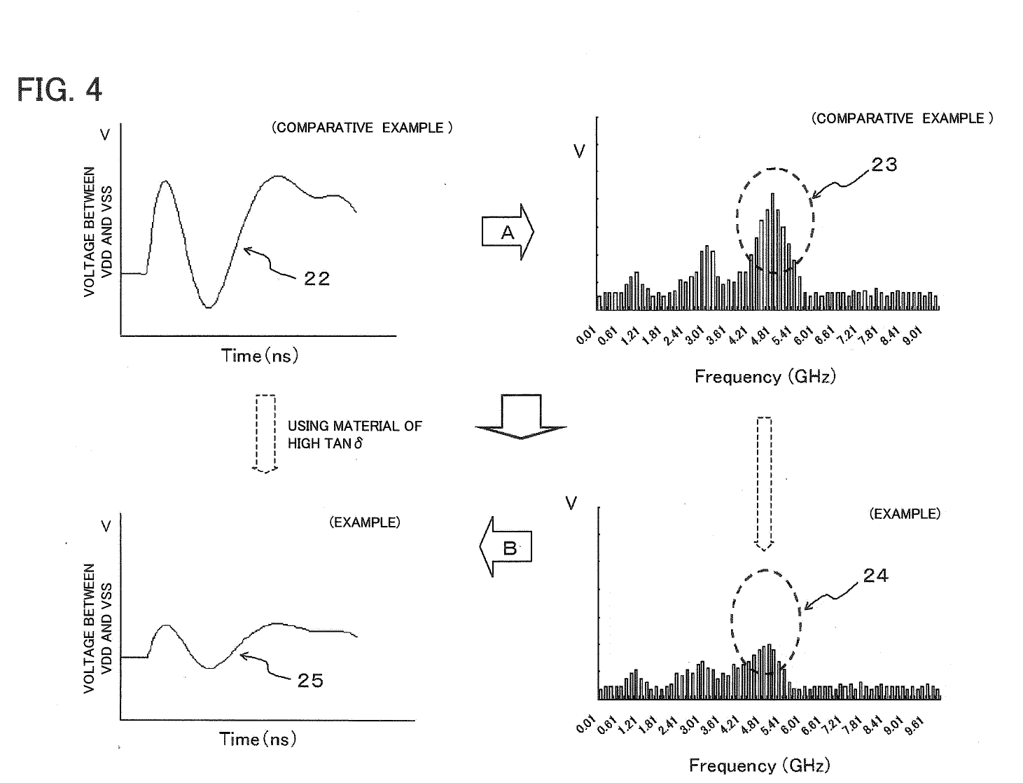

Next, the operation of the dielectric of the second dielectric layer 5 is explained with reference to the drawings. FIG. 2 is a cross-sectional view of a simulation model of the ground wiring layer, the second dielectric layer and the power supply wiring layer of the semiconductor device in accordance with example 1 of the present invention. FIG. 3 is a graph obtained by an electromagnetic field simulation by the model of FIG. 2 to explain a transmission loss between the power supply wiring layer and the ground wiring layer. FIG. 4 is a graph to explain the noise between the power supply and ground wirings when a driver of the semiconductor device according to example 1 is operated at an operation frequency of 1 GHz.

A piece of Cu (copper) of a size 1×1×0.02 mm in dimension (length, width, height), 5.8×10⁷ (Siemens/m) in conductivity and 1 (H/m) in permeability was used for the ground wiring layer 14 in the simulation model of FIG. 2. Two kinds of dielectric materials of 1×1×0.05 mm in dimension (length, width, height), 3.4 in permittivity, and dielectric loss tan δ=0.02 (comparative example; low tan δ material) and 1.00 (example; high tan δ material) were used as the second dielectric layer 15. A piece of Cu (copper) of a size 1×1×0.02 mm in dimension (length, width, height), 5.8×10⁷ (Siemens/m) in conductivity and 1 (H/m) in permeability was used as the power supply wiring layer 16. Namely, the ratio of the high dielectric loss tan δ to the low dielectric loss tan δ amounts to 50.

An analysis space 17 is the analysis space for simulation and is assumed as the air of 3×3×1 mm in dimension (length, width, height). The ground wiring layer 14, the second dielectric layer 15 and the power supply wiring layer 16 are set at the center of the analysis space 17. The surface of the analysis space 17 is assumed to be a perfect conductive surface (conductivity=∞) as a boundary condition.

A high frequency three dimensional electromagnetic field simulator (HFSS) (Ansoft Corp.) was used within a range of frequency from 50 MHz to 10 GHz.

A transmission loss curve 18 in FIG. 3 shows the transmission loss (S21) on the condition that the dielectric loss (tan δ) is 1.00 (example) whereas a transmission loss curve 19 shows the transmission loss (S21) on the condition that the dielectric loss (tan δ) is 0.02 (comparative example). An attenuation loss difference 20 at the frequency of 1 GHz is 1 dB, in contrast, an attenuation loss difference 21 at the frequency of 5 GHz is approximately 3 dB.

A signal waveform 22 of FIG. 4 indicates a voltage waveform versus the time axis, of noise occurring between the power supply wiring and ground wiring in the semiconductor device in accordance with the comparative example (of low tan δ material). A graph marked at 23 shows the noise components of frequency transformed into frequency axis by the Fourier transform (arrow A) of the signal waveform 22 in accordance with the comparative example. As we recognize by the graph 23, the noise frequency comprises mainly an operating frequency, 1 GHz, and harmonic components thereof, and has its strong tendency at higher frequency components.

A graph marked at 24 of FIG. 4 indicates a graph of frequency components transformed from a voltage waveform of noise occurring between the power supply wiring and ground wiring in the semiconductor device in accordance with the example (of high tan δ material). A 5 GHz harmonic component of the operation frequency is reduced greatly in the graph marked at 24. A signal waveform 25 of the noise versus the time axis can be obtained by inverse Fourier transform (arrow B) of the graph 24 in accordance with the example. Compared to the signal waveform 22 in accordance with the comparative example, voltage amplitude of the signal waveform 25 in accordance with the example becomes small, that is, the noise is suppressed significantly. That is because the dielectric loss tan δ of the example is greater and the high frequency noise components occurred during a high-speed operation of a device are transformed into heat and so on, since the transmission loss at the power supply wiring becomes larger.

According to example 1, noise occurred between a power supply wiring and ground wiring by a simultaneous switching of signals can be reduced efficiently. When high-speed operation signals pass on a wiring pattern of multi-layer wiring portion, most part of the noise current comprise high frequency components. Similarly most of the noise current on the power supply wiring layer comprise high frequency components (see 23 of FIG. 4). And the higher the frequency is, the greater the portion of the dielectric loss of dielectric is (see 19 and 20 of FIG. 3) and the noise is reduced (see 24 of FIG. 4) because the voltage at high frequency portion becomes small. In short, by using a higher dielectric loss (tan δ) material than the FR4 (tan δ=0.02 to 0.03) used for dielectric generally, the dielectric behaves as a low pass filter and absorb the high frequency components occurred between the power supply wiring and ground wiring and can reduce the noise. For this purpose, the ratio of the higher dielectric loss tan δ to the lower dielectric loss tan δ amounts to preferably 5 or more, more preferably 6 to 10, ranging up to at least 50.

### EXAMPLE 2

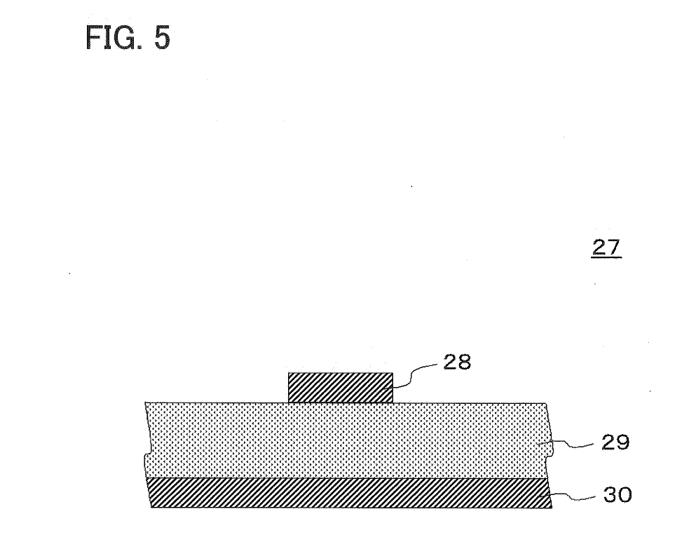

Next, a semiconductor device in accordance with example 2 of the present invention is described with reference to drawings. FIG. 5 is a partial cross-sectional view for illustrating a semiconductor device in accordance with example 2 of the present invention.

A high dielectric loss material is used for the dielectric layer between a power supply wiring layer and a ground wiring layer in example 1. In contrast, a high dielectric loss material is used for the dielectric layer between a signal wiring layer and a ground wiring layer in example 2.

A semiconductor device 27 shows a semiconductor package (micro-computer or memory, for example) in which circuit-patterned semiconductor chips are mounted on a package board, or a mounting board (memory module or mother board, for example) mounting a semiconductor package onto a circuit board. The semiconductor device 27 contains a signal wiring layer 28, a first dielectric layer 29 and a ground wiring layer 30 in the wiring board portion of a package board, circuit board and so on (not shown).

The signal wiring layer 28 is a wiring layer for signal transmission made of a conductor and disposed on the first dielectric layer 29 with a determined pattern. A metal, e.g., cupper, can be used for the signal wiring layer 28. The thickness of the signal wiring layer 28 can be 0.01 to 0.03 mm, for example.

The first dielectric layer 29 is a layer made of dielectric (insulator) and interposed between the signal wiring layer 28 and the ground wiring layer 30. For the first dielectric layer 29, dielectric materials having the same dielectric loss (tan δ is greater or equal to 0.2) of the second dielectric layer (reference number 5 in FIG. 1) of example 1 is used. The thickness of the first dielectric layer 29 can be 0.02 to 0.08 mm, for example. Besides, the dielectric loss of the first dielectric layer 29 will be changed higher within such a range not to degrade the signal quality according to the characteristics of each device (semiconductor chip).

The ground wiring layer 30 is a wiring layer for ground made of conductor and disposed on one side of the first dielectric layer 29 at the opposite side to the signal wiring layer 28. A metal, e.g., cupper, can be used for the ground wiring layer 30. The thickness of the ground wiring layer 30 can be 0.01 to 0.03 mm, for example.

Operation of the semiconductor device according to example 2 will be explained. When the signal wiring layer 28 and ground wiring layer 30 is on (conducting), a transmission loss generated in the first dielectric layer 29 reduces the noise occurred in the signal wiring layer 28.

According to example 2, it has the same effect of example 1.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A semiconductor device, wherein a dielectric material whose dielectric loss tan δ is at least 0.2 is used for a dielectric layer interposed between a power supply wiring layer electrically connected to a semiconductor chip and a ground wiring layer.

2. The semiconductor device of claim 1, wherein said semiconductor device is so composed that a transmission loss generated in said dielectric layer acts as a low pass filter of said power supply wiring layer.

3. The semiconductor device of claim 1 further comprising; another dielectric layer interposed between a signal wiring layer electrically connected to said semiconductor chip and said ground wiring layer, wherein a dielectric material having a dielectric loss less than said dielectric loss tan δ of said dielectric layer is used for said another dielectric layer.

4. The semiconductor device of claim 2 further comprising; another dielectric layer interposed between a signal wiring layer electrically connected to said semiconductor chip and said ground wiring layer, wherein a dielectric material having a dielectric loss less than said dielectric loss tan δ of said dielectric layer is used for said another dielectric layer.

5. The semiconductor device of claim 1, wherein the dielectric loss tan δ of said dielectric layer is large to an extent that does not deteriorate the signal quality.

6. The semiconductor device of claim 1, wherein the dielectric loss tan δ is not more than 1.

7. A semiconductor device, wherein a dielectric material whose dielectric loss tan δ is at least 0.2 is used for a dielectric layer interposed between a signal wiring layer electrically connected to a semiconductor chip and a ground wiring layer.

8. The semiconductor device of claim 5, wherein said semiconductor device is so composed that a transmission loss generated in said dielectric layer reduces noise occurred in said signal wiring layer.

9. The semiconductor device of claim 7, wherein the dielectric loss tan δ of said dielectric layer is large to an extent that does not deteriorate the signal quality.

10. The semiconductor device of claim 7, wherein the dielectric loss tan δ is not more than 1
